(19) United States
(12) Patent Application Publication
(10) Pub. No.: US 2022/0382926 A1
(43) Pub. Date: Dec. 1, 2022

(54) SIMULATION-BASED CORRIDOR DESIGN FOR CONNECTED AUTONOMOUS VEHICLES

(71) Applicant: Ford Global Technologies, LLC, Dearborn, MI (US)

(72) Inventors: Archak Mittal, Canton, MI (US); James Fishelson, Ypsilanti, MI (US); Richard Twumasi-Boakye, Taylor, MI (US); Yifan Chen, Ann Arbor, MI (US); Xiaolin Cai, Ann Arbor, MI (US); Eric H. Wingfield, Ann Arbor, MI (US)

(73) Assignee: Ford Global Technologies, LLC, Dearborn, MI (US)

(21) Appl. No.: 17/334,115

(22) Filed: May 28, 2021

(51) Int. Cl. G06F 30/13; G06F 30/20

(52) U.S. Cl. CPC G06F 30/13; G06F 30/20

(57) ABSTRACT

A method for generating an infrastructure management plan is described. The method may include determining, via a Regional Traffic Simulation (RTS) model, an opportunity area for connected and automated vehicle (CAV) integrated traffic flow. Generating a regional key performance indicator associated with the opportunity area and modeling a regional KPI associated with local traffic in the opportunity area using a Local Traffic Simulation (LTS) model. The method may further include determining a local KPI associated with the opportunity area, generating a tentative traffic solution associated with the opportunity area, connecting the LTS model to the RTS model using an outer feedback loop, and determining a ripple effect of the tentative traffic solution via the RTS model. The method concludes with generating the infrastructure management plan comprising the change to the LTS model responsive to confirming an improvement to the regional KPI and the local KPI.

### TECHNICAL FIELD

The present disclosure relates to simulation-based infrastructure design, and more particularly, to simulation-based corridor design with dedicated lanes for connected autonomous vehicles.

### BACKGROUND

As Connected and Automated Vehicles (CAVs) are integrated with human-driven vehicles on roadways, regional and local roadway infrastructure managers encounter new challenges as they address traffic flow, energy efficiency, and driver experience issues. Some regional planning bodies and governments have begun to implement dedicated CAV lanes that promise improved traffic flow. The corridor concept allows for highly autonomous driving on dedicated CAV lanes, promising better traffic flow, higher energy efficiency and superior rider experience, among others.

However, this is a completely new mobility concept, involving both novel vehicle types and restructure where the knowledge and experience are lacking. For instance, it is expected to take two full years just to complete the feasibility phase of the Michigan Connected Corridor concept.

It is with respect to these and other considerations that the disclosure made herein is presented.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 depicts an example flow diagram for Connected and Automated Vehicle corridor design using a CAV corridor design system in accordance with the present disclosure.

FIG. 2 illustrates a flow diagram of a simulation-based design framework for the CAV corridor design system of FIG. 1 in accordance with the present disclosure.

FIG. 3 depicts a cloud computing environment in accordance with the present disclosure.

FIG. 4 depicts a flow diagram of an example method for generating an infrastructure management plan in accordance with the present disclosure.

### DETAILED DESCRIPTION

### Illustrative Embodiments

The disclosure will be described more fully hereinafter with reference to the accompanying drawings, in which example embodiments of the disclosure are shown, and not intended to be limiting.

However, CAV lane designation is a completely new mobility concept, involving both novel vehicle types and restructuring CAV lane design and integration where the knowledge and experience may not provide clear design guidelines due to the nascence of such infrastructure. It may be advantageous to provide a system and method for integrating both macro scale and micro scale modeling, where the macro scale design model is fed back into the micro scale model to test the impact of local and regional infrastructure changes.

Moreover, embodiments of the present disclosure may provide insights into predicted and unpredicted effects of systematic changes in the micro scale (e.g., local roadway opportunity areas in one linear mile or smaller areas) as they cause effects in other areas of the region (e.g., the macro scale such as a city or similar geographic study area). One main outcome of this system is the ability to identify a new mode of travel based on a systematic approach of collecting and analyzing data from both of a macro level and a micro level. This system may assist in developing CAV corridors using data from a single existing CAV corridor as a model that provides testing and predictive analytics.

Substantial experience exists for building infrastructure and designing solutions for traffic for traditional modes of travel (cars, trucks, bikes, etc.). However, CAVs represent a fundamentally new mode of travel. While there does currently exist some knowledge transfer of engineering practice from other (non-CAV) transportations modes such as BRT (Bus Rapid Transit), there is no direct experience or “playbook” for design an effective/efficient CAV corridor. Examples include designing the relationship between CAVs and the infrastructure (e.g., traffic signal timing or corridor ingress/egress), inter-CAV relationships (for example, platooning strategies), and managing interactions between CAV and regular vehicles, pedestrians, bikes, and other transportation modes. Moreover, state and local governments have over 70 years of transportation modeling and traffic simulation data that may provide important data points for design of CAV lanes and other infrastructure. The CAV corridor design system described according to embodiments of the present disclosure may leverage these sources for real time and historic planning data in an integrated and self-improving way to generate CAV corridor design output that satisfies local and regional needs.

Conventional modeling and traffic simulation may be used as inputs to the present CAV corridor design system using macroscopic modeling, microscopic modeling, and nanoscopic modeling. Macroscopic modeling methods, as used herein, may examine metropolitan travel patterns as a whole. In some aspects, a macroscopic model approach also examines overall flows at the roadway level rather than at the level of individual vehicles. This may provide long-term planning of how people move through a metropolitan region.

Mesoscopic modeling methods, as used herein, may be used in shared-mobility and agent-based modeling. This approach examines individual trips taken by travelers in a given region, which makes such a modeling approach usable in multi-modal studies. Mesoscopic modeling may simulate individual trips, and can supplement other modeling approaches. Microscopic modeling may also simulate the movement of individual vehicles and examines localized impacts (such as, for example, implementation or changes to a traffic signal). This approach represents the most detailed modeling type for examining vehicle-to-vehicle (V2V), vehicle-to-infrastructure (V2I) and CAV communications.

According to one or more embodiments, the CAV corridor design system may apply transportation modeling and traffic simulation in a unique, integrated and iterative way to help answer key design questions, including 1) the physical appearance of proposed infrastructure, such as acceptable entry/egress points, dedicated lanes in center or along curb, and other physical attributes, 2) traffic control effects such as traffic signal priority for CAVs, allowable turning movements, and other such design decisions, and 3) variable behaviors such as vehicle behavior, including CAVs changing behavior in and outside of lanes, and types of connectivity between vehicles and infrastructure, among other inquiries.

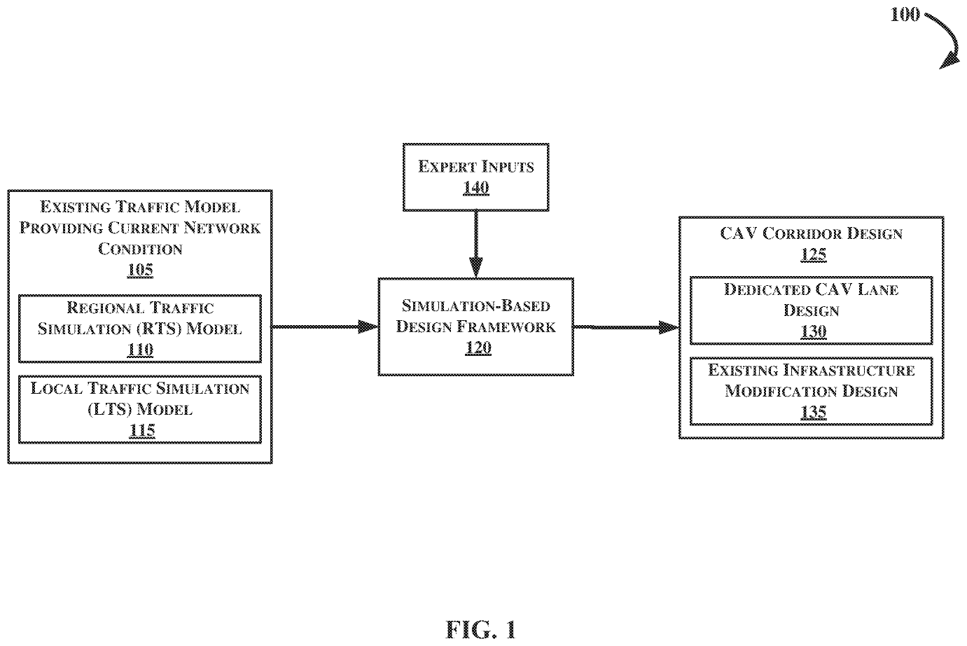

FIG. 1 depicts an example flow diagram for Connected and Automated Vehicle corridor design using a CAV corridor design system 100, in accordance with the present disclosure. As CAV corridors require transformative changes in road structure, neighboring land use, and other infrastructure, there is a need for design criteria and key performance indicators (KPIs) for effective use and effective investment. However, designing a CAV corridor is both fully novel and too complex (too many interactions and shareholders) for classic optimization or “trial and error” pilot approaches to work effectively.

The CAV corridor design system 100 may coordinate elements of an iterative and integrated solution that links modeling and design, and includes multi-scale modeling comprising microscopic modeling for operational level fidelity and simulation of individual vehicle behaviors, which may include co-simulation with nanoscopic models at the intra-vehicle level that simulates detailed autonomous vehicle (AV) logic. Existing traffic models providing current network conditions 105 may be used as input to the simulation-based design framework 120. Embodiments may further include mesoscopic inputs for activity-based models to simulate shared use and multimodality (e.g., a traveler may take a scooter to a hub on the CAV corridor to transfer to an automated corridor transit shuttle). These may include a local traffic simulation (LTS) model 115.

Embodiments may further include macroscopic regional impact analysis using a regional traffic simulation (RTS) model 110, which can include input into mesoscopic and microscopic scale, with iterative feedback.

A simulation-based design framework 120 may be used to combine various data sets (e.g. travel demand, traffic signal timing, and more) with user surveys and regulatory and policy requirements. Expert inputs 140 may further be utilized in the simulation-based design framework 120 to provide expert guidance in areas of high uncertainty. The simulation-based design framework 120 may be constantly improved via a machine learning framework.

The output of the CAV corridor design system 100 may include a CAV corridor design 125, which may include a novel and flexible CAV corridor design suited to different needs and use cases that may be specific to a geographic region or local roadway. This may include dedicated CAV lane design 130, and/or include existing infrastructure modification design 135. The CAV corridor design 125 may be balanced against diverse goals for optimized solutions at regional and road segment scales. The solutions provided in the CAV corridor design 125 are ideally inexpensive, rapid, and iterative through potential solutions to limit decision matrices and provide deployment pathways. This approach provides an iterative computer-based system disposed for quantitative and science-based investment planning instead of trial and error or based solely on expert recommendations, as done in conventional planning systems.

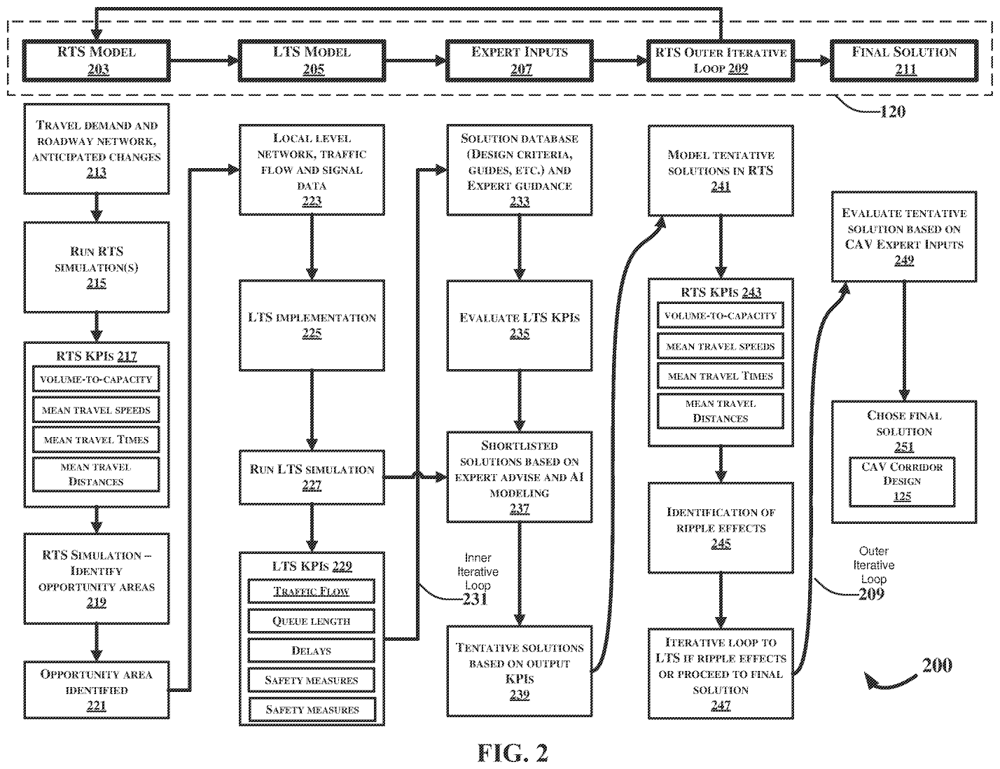

FIG. 2 illustrates a flow diagram of an example simulation-based design framework 200 for the CAV corridor design system 100, in accordance with the present disclosure. A simulation-based design approach can link modeling to design by rapidly incorporating testing and resolving criteria for road design for CAV infrastructure. The simulation-based design approach of FIG. 2 can include planning and goal setting for shared road use, throughput of goods and services on planned roadways, integration of new or modified safety systems, traffic flow management, and other aspects. The CAV corridor design system 100 may utilize RTS KPIs and LTS KPIs to generate simulation-based final solutions for CAV roadway infrastructure. Potential KPIs can include: traffic flow, travel delays, volume of goods and services, transit, and personal vehicle use, signal timing effectiveness, and overall safety metrics, among others.

Three main design categories and/or criteria may be used to impact CAV infrastructure design, with sample design decisions and relevant modeling scales included for each design category. These design categories may include physical appearance of the infrastructure (e.g., fixed infrastructure), traffic control, and vehicle behavior, among other possible design categories.

The simulation-based design framework 120 includes an iterative process flow that including a Regional Traffic Simulation (RTS) model 203 that may model travel demand from inputs and data provided by state and/or regional authorities providing information about how vehicles move within the state or region. The RTS model 203 may observe regional traffic flows and patterns, and identify local traffic areas that may experience congested traffic flow patterns (referred to herein as opportunity areas).

The RTS model 203 may output a regional traffic simulation to a Local Traffic Simulation (LTS) model 205. The LTS model 205 is microscopic by nature, allowing the CAV corridor design system 100 to see how vehicles react on the road. The LTS model 205 may generate traffic intervention models that can implement particular traffic flow changes within a microscopic or local area. For example, the RTS model may identify a hot spot or area of congested traffic flow patterns, and push that information back to the LTS model in an outer iterative loop 209 following additional expert inputs 207. The LTS model 205 may model one or more particular interventions such as a turn lane change, for example.

Expert inputs 207 are added to the output of the local traffic simulation output, and can include observations and data provided by industry experts with experience in engineering knowledge in CAV implementation and policy. After the CAV corridor design system 100 receives expert inputs 207, the RTS outer iterative loop 209 may test the impact of design changes at the local level (from the LTS model 205) to find and observe ripple effects in the RTS model 203. Once a satisfactory steady state is observed in the multi-modal modeling, a final solution 211 is generated by the CAV corridor design system 100. A satisfactory steady state may be, for example, one or more KPIs that have been selected as indicators of design optimization and generate results in the modeled systems as being within acceptable values (e.g., user-defined ranges). KPIs are discussed hereafter in the following sections, at least, at blocks 217 and 243.

The simulation-based design framework 200 includes a plurality of steps shown in FIG. 2 beneath each of the main simulation-based design steps, respectively. Starting with block 213, the CAV corridor design system 100 may receive travel demand and roadway network information from one or more state or regional authorities. This may include collecting input data such as regional-level travel demand and roadway network information. This step may further include collecting anticipated changes to the roadway network. In some aspects, travel demand and roadway network data serve should be calibrated with real-world data to emulate current conditions. In travel demand modeling framework, the demand is calibrated to ensure that mode splits correspond to observed data collected from surveys. Subsequently, in a traffic assignment step, the traffic volumes on the network are compared with traffic counts to ensure that they are within acceptable error margins. Anticipated changes may include future cases to incorporate CAVs, AVs, hypothetical or planned infrastructure changes, road additions or re-routing, etc. Such anticipated changes may also include modifications to the transportation operations that are anticipated in the area. For example, it may be anticipated that there will exist increased demand in a particular region or local area, and/or more or less CAV traffic may be anticipated. Accordingly, anticipated changes may refer to anticipated future changes to infrastructure, or changes with respect to vehicle traffic or road/lane usage.

At block 215, after collecting the initial inputs, the CAV corridor design system 100 may run Regional Traffic Simulation(s) (RTSs) for a anticipate future scenario. This step can include utilizing macroscopic traffic simulation tools such as, for example, PTV Visum®, TransCAD®, or other similar platform modelers to execute RTS simulations. Accordingly, the CAV corridor design system 100 may import the data from block 213, and run an initial RTS simulation to generate a baseline simulation that may be used as a first step calibration base model for identification of one or more opportunity areas in which operational problems may be addressed.

At block 217 the CAV corridor design system 100 may generate one or more RTS KPIs. The indicators that may be generated as part of the RTS KPIs can include volume-to-capacity metrics, mean travel speeds, mean travel times, mean travel distances, and other such performance indicators.

At block 219, if the KPIs computed in block 217 indicate opportunity areas (e.g., corridor traffic hotspots) at the regional level, at block 221 the CAV corridor design system 100 may review high congestion or other traffic problems that may be specifically localized (e.g., at a local level). Responsive to determining that opportunity areas exist, the RTS model 203 may hand over the analysis to local level module (e.g., the LTS model 205).

At block 223, the LTS model 205 may identify local level network, traffic flow information and signal data that may have an impact on the opportunity area, or stated in another way, affect the local corridor traffic hotspots by improving the situation by increasing traffic flow, diminishing the performance of the hotspots by decreasing the traffic flow, or having little or no effect on the hotspots.

At block 225 the LTS implementation may be executed using the LTS model 205, at the local level, using a microscopic traffic simulator. This step may be used to analyze the identified opportunity area, such as a one-mile road segment. This step may also address localized operational needs to create affective design solutions. For example, at local level, a solution method may take the following sequential steps: First, the system may collet required input data for the attention area, such as local level network, traffic flow and signal data from block 223. The data collected at block 223 may ideally be calibrated with real-world data to emulate current conditions. For example, the CAV corridor design system 100 may take historic data provided by state, regional, or local traffic authorities, and supplement that data with real-time information received from on-the-road infrastructure communication systems.

At block 227 the CAV corridor design system 100 may run the LTS simulation using the LTS model 205, which is a microscopic simulation analysis.

At step 229, the system may identify one or more LTS KPIs that can include, for example, traffic flow at the localized hotspot, queue length, delays, and may include identification and/or quantification of safety measures such as barriers, traffic diversion signage, or other measures such as signal prioritization for CAVs, Bus Rapid Transit (BRT), Emergency Vehicle access or routing, and/or shared service access such as AV shuttles. Accordingly, the system may measure infrastructural changes to make sure of the safety of vehicles egressing/digressing of the CAV lanes so they have comfortable room and time to maneuver.

At step 231, the CAV corridor design system 100 may execute an inner iterative loop. The inner iterative loop may constitute local level iterations in a feedback loop between solution choice-set and microscopic traffic simulator. In one aspect the iteration may continue until one or more superior solutions (e.g., solutions that meet or exceed the KPI's generated at block 229) are identified for CAV integration on roadway. The focus of block 231 may be to generate a final set of viable CAV orchestrations and contribute to a database (e.g., a solutions database at step 233) to inform continuous learning process for future projects.

At step 233, the solutions database may also include domain expert and knowledge provided by one or more domain experts. Accordingly, the CAV corridor design system 100 may generate a request to one or more domain experts requesting an evaluation input for generation of a shortlist of solutions that may be tested in an outer iterative loop (e.g., the outer iterative loop 209). This step may guide solution integration into microscopic simulation for a second iterative modeling at LTS simulation 227 during a second or Nth iteration. The expert guidance may also evaluate KPI outputs from the microscopic simulation at the LTS model 205, which may be useful for identification of the optimal solution (e.g., the final solution 251 discussed hereafter). Accordingly, at block 235, the CAV corridor design system 100 may evaluate the LTS KPIs having expert inputs 207.

The solutions database may be used by the CAV corridor design system 100 to guide effective implementation on CAV and corridor cognizant design criteria. This may include experience on roadway implementation, based on domain expert evaluation of KPIs from microscopic simulation at block 227. The solutions database may further contain implementation outcome and effectiveness as a function of local conditions on different segments of roadway corridor and different technology implementations. The solutions database may be based on literature review, design manual, expert opinion, and other sources. Example solutions can include, for example, curbside dedicated CAV lane implementation, center-lane dedicated CAV Lane implementation, signal optimization, infrastructure design (e.g. design that accounts for pedestrian traffic, personal transport vehicle traffic, etc.), or other infrastructure design elements.

In some aspects, the process may circle back from the inner loop. For example, if the system identifies multiple acceptable remedy solutions for LTS, the process may iterate back to LTS after fine tuning the parameters and running the simulation again.

At block 237, a shortlisted solution based on the expert advice and AI modeling may be generated by the CAV corridor design system 100. The shortlisted solution is a subset of the solution database at block 233, which may contain a choice set of potential solutions that may remedy the local traffic hotspot at issue. For example, a change of traffic flow may be included in the shortlist. In another example, a speed change may be recommended, or one or more other solutions that have an effect on traffic speed, throughput, emissions, delays, or safety concerns.

At step 239, one or more tentative solutions may be selected by the CAV corridor design system 100 based on output KPIs associated with the shortlisted solutions. For example, the CAV corridor design system may test different dedicated CAV lane placement strategies, and signal optimization methods. These implementations will result in a choice set of feasible solutions based on KPIs (e.g., high throughput, minimized congestion, fewer conflicts) to be tested in the RTS outer loop.

At step 241, the RTS outer iterative loop 209 begins, where tentative solutions may be modeled in the RTS model 203. The outer iterative loop 209 represents a feedback loop between microscopic and regional simulation for ripple-effect evaluation at regional level. In some aspects, any solution-informed change at the micro-level that can be represented at the regional-level may be run through the RTS model 203 to assess city-wide repercussions (e.g., the “ripples”). Examples can include changing a count of lanes, modifying the location of an intersection, changing transit routes, etc.

In the outer iterative loop 209, at block 243, the RTS KPIs may be re-analyzed in view of the tentative solutions based on output KPIs, and identification of any ripple effects may be performed at block 245.

Responsive to determining at block 247 that the ripple effects are tolerable, minimal, or not existing, at block 249 the CAV corridor design system 100 may evaluate a tentative solution based on the CAV expert input at block 249. This step can include reviewing the final solution generated by the iterative process. For example, the system may choose a final solution based on the following sequential steps:

1) Evaluating a tentative solution based on CAV expert advisory;

2) Reviewing and comment by a CAV Expert on the tentative solution generated;

3) Choosing a final solution based on stakeholder discussions/policy; and

4) Review the policy requirement by a stake holder and select the final solutions through discussion.

At block 251, a final solution is chosen, and the CAV corridor design 125 may be finalized. Final solutions may include, for example, implementation of a right-hand lane for CAVs, implementation of a turn zone for CAVs and non-CAVs, time signals by mode as identified by each respective intersection, and/or upgrading signals on road networks adjacent to a CAV corridor. Although these example solutions provide practical examples of solutions that may be implemented, it should be understood that any number or type of solution may be realized by embodiments of the present disclosure.

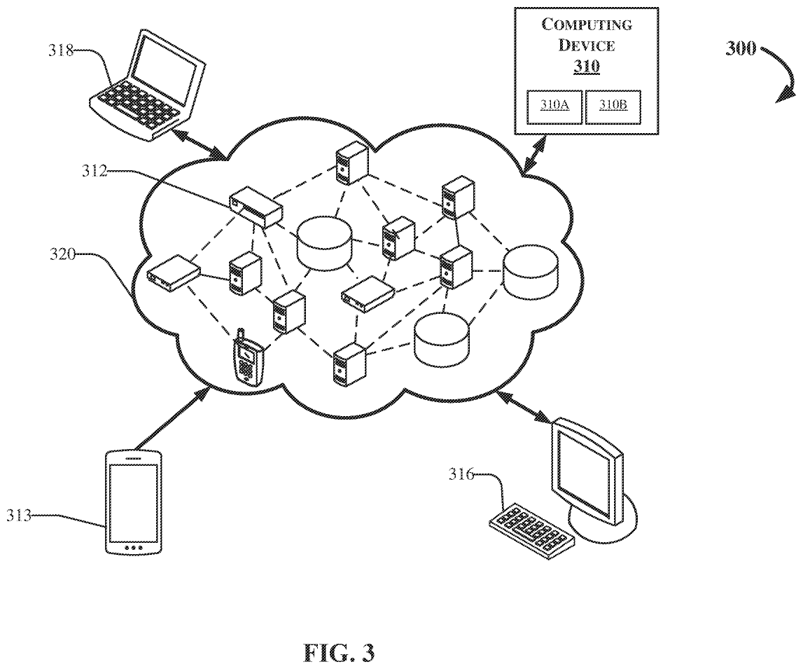

FIG. 3 depicts a cloud computing environment in accordance with the present disclosure. In FIG. 3, a computing device 310 including components such as processor 310A and memory 310B, is in communication with a cloud system network 320 that includes a plurality of storage devices 312. The cloud can be accessed by a variety of computer devices including handheld computers 313, a desk top computer(s) 316 and a laptop computer(s) 318.

To that end, the computer system suitable for practicing the method of this disclosure may include one or more processor(s), and a memory communicatively coupled to the one or more processor(s). The computer may operatively connect to and communicate information with one or more internal and/or external memory devices such as, for example, one or more databases via a storage interface. For example, in one embodiment, the computer may connect to and communicate information with an internal and/or external database, such as a profile database (referenced as the user data).

The computer may include one or more network adaptor(s) (not shown in FIG. 3) enabled to communicatively connect the computer with the one or more network(s). In some example embodiments, the network(s) may be or include a telecommunications network infrastructure. In such embodiments, the computer can further include one or more communications adaptor(s).

The computer may further include and/or connect with one or more input devices and/or one or more output devices (not shown in FIG. 3) through an I/O adapter.

The one or more processor(s) are collectively a hardware device for executing program instructions (aka software), stored in a computer-readable memory. The one or more processor(s) may embody a custom made or commercially-available processor, a central processing unit (CPU), a plurality of CPUs, an auxiliary processor among several other processors associated with the computer, a semiconductor based microprocessor (in the form of a microchip or chipset), or generally any device for executing program instructions.

The one or more processor(s) may be disposed in communication with one or more memory devices (e.g., the memory and/or one or more external databases, etc.) via a storage interface. The storage interface can also connect to one or more memory devices including, without limitation, one or more other memory drives, including, for example, a removable disc drive, cloud storage, etc., employing connection protocols such as serial advanced technology attachment (SATA), integrated drive electronics (IDE), IEEE-1394, universal serial bus (USB), fiber channel, small computer systems interface (SCSI), etc.

The memory can include random access memory (RAM) such as, for example, dynamic random access memory (DRAM), synchronous random access memory (SRAM), synchronous dynamic random access memory (SDRAM), etc., and read only memory (ROM), which may include any one or more nonvolatile memory elements (e.g., erasable programmable read only memory (EPROM), flash memory, electronically erasable programmable read only memory (EEPROM), programmable read only memory (PROM), tape, compact disc read only memory (CD-ROM), etc.). Moreover, the memory can incorporate electronic, magnetic, optical, and/or other types of non-transitory computer-readable storage media. In some example embodiments, the memory may also include a distributed architecture, where various components are physically situated remotely from one another, but can be accessed by the one or more processor(s).

The instructions in the memory can include one or more separate programs, each of which can include an ordered listing of computer-executable instructions for implementing logical functions. The instructions in the memory can include an operating system.

The program instructions stored in the memory can further include application data, and instructions for controlling and/or interacting with the computer through a user interface. The application data may include, for example, one or more databases.

The I/O adapter can connect a plurality of input devices to the computer. The input devices can include, for example, a keyboard, a mouse, a microphone, a sensor, etc. The I/O adapter can further include a display adapter coupled to one or more displays. The I/O adapter can be configured to operatively connect one or more input/output (I/O) devices to the computer. For example, the I/O adapter can connect a keyboard and mouse, a touchscreen, a speaker, a haptic output device, or other output device. The output devices can include but are not limited to a printer, a scanner, and/or the like. Finally, the I/O devices connectable to the I/O adapter can further include devices that communicate both inputs and outputs, for instance but not limited to, a network interface card (NIC) or modulator/demodulator (for accessing other files, devices, systems, or a network), a radio frequency (RF) or other transceiver, a telephonic interface, a bridge, a router, and the like.

As can be seen, the method and system of the present disclosure has a broad scope of applicability in the transportation field. For example, it is capable of being applied across a wide variety of geographic areas of varying sizes and population densities, not to mention a wide cross-section of transportation networks, microtransit systems and their service parameters. In fact, this method can be expanded to other forms of mobility services, such as, micro mobility solutions.

The disclosed methods can provide a number of advantages over existing simulations. For example, the method can provide a cost-benefit analysis of a number of possible microtransit scenarios at the same time, thus, providing a fast decision-making process and a more efficient business operation.

Moreover, the method is in the form of a fully digital tool, independent of any specific commercial simulation tool or data type, which aids in determining both market access and market profitability. In fact, the method can identify cases and constraints under which shared mobility services may thrive from the operator's perspective including the optimal service operation for various geographic locations based on the demand profiles and the travel needs for those locations.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation. All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

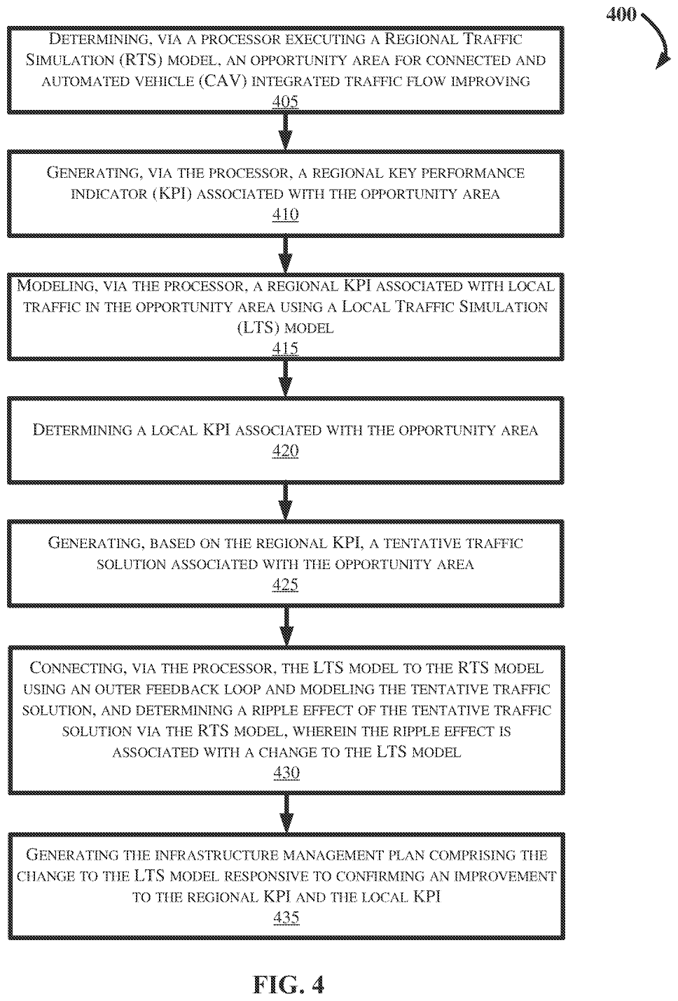

FIG. 4 is a flow diagram of an example method 400 for generating an infrastructure management plan, according to the present disclosure. FIG. 4 may be described with continued reference to prior figures, including FIGS. 1-3. The following process is exemplary and not confined to the steps described hereafter. Moreover, alternative embodiments may include more or less steps that are shown or described herein, and may include these steps in a different order than the order described in the following example embodiments.

Referring first to FIG. 4, at step 405, the method 400 may commence with determining, via a processor executing a Regional Traffic Simulation (RTS) model, an opportunity area for connected and automated vehicle (CAV) integrated traffic flow. In one aspect, the RTS model may include one or more macroscopic traffic simulation tools programmed for microscopic traffic simulation.

At step 410, the method 400 may further include generating, via the processor, a regional key performance indicator (KPI) associated with the opportunity area. This step may include generating a KPI associated with regional traffic comprises a mean travel time. In another aspect, this step may include generating a KPI associated with a mean travel speed. In yet another aspect, this step may include generating a KPI associated with a volume-to-capacity ratio.

At step 415, the method 400 may further include modeling, via the processor, a regional KPI associated with local traffic in the opportunity area using a Local Traffic Simulation (LTS) model. The LTS model may include a microscopic traffic simulation tool programmed for generating key performance indicator data for traffic flow, queue length, traffic delays, and traffic safety information.

At step 420, the method 400 may further include determining a local KPI associated with the opportunity area. This step may include collecting travel demand data, collecting roadway network data, collecting infrastructure change information having data associated with one or more anticipated regional traffic infrastructure changes, and/or benchmarking a traffic condition based on one or more of the travel demand data, roadway network data, and the infrastructure change information.

At step 425, the method 400 may further include generating, based on the regional KPI, a tentative traffic solution associated with the opportunity area.

At step 430, the method 400 may further include connecting, via the processor, the LTS model to the RTS model using an outer feedback loop and modeling the tentative traffic solution, and determining a ripple effect of the tentative traffic solution via the RTS model, wherein the ripple effect is associated with a change to the LTS model. This step may include generating a tentative solution that can include changing a count of lanes, modifying the location of an intersection, and/or changing transit routes. Other tentative solutions are contemplated, and such solutions are possible.

At step 435, the method 400 may further include generating the infrastructure management plan comprising the change to the LTS model responsive to confirming an improvement to the regional KPI and the local KPI.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a feature, structure, or characteristic is described in connection with an embodiment, one skilled in the art will recognize such feature, structure, or characteristic in connection with other embodiments whether or not explicitly described.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description and claims refer to particular system components. As one skilled in the art will appreciate, components may be referred to by different names. This document does not intend to distinguish between components that differ in name, but not function.

It should also be understood that the word “example” as used herein is intended to be non-exclusionary and non-limiting in nature. More particularly, the word “example” as used herein indicates one among several examples, and it should be understood that no undue emphasis or preference is being directed to the particular example being described.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Computing devices may include computer-executable instructions, where the instructions may be executable by one or more computing devices such as those listed above and stored on a computer-readable medium.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating various embodiments and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A method for generating an infrastructure management plan, comprising:
determining, via a processor executing a Regional Traffic Simulation (RTS) model, an opportunity area for connected and automated vehicle (CAV) integrated traffic flow;
generating, via the processor, a regional key performance indicator (KPI) associated with the opportunity area;
modeling, via the processor, a regional KPI associated with local traffic in the opportunity area using a Local Traffic Simulation (LTS) model,
determining a local KPI associated with the opportunity area;
generating, based on the regional KPI, a tentative traffic solution associated with the opportunity area;
connecting, via the processor, the LTS model to the RTS model using an outer feedback loop and modeling the tentative traffic solution, and determining a ripple effect of the tentative traffic solution via the RTS model, wherein the ripple effect is associated with a change to the LTS model; and
generating the infrastructure management plan comprising the change to the LTS model responsive to confirming an improvement to the regional KPI and the local KPI.

2. The method according to claim 1, wherein the RTS model comprises a macroscopic traffic simulation tool programmed for microscopic traffic simulation.

3. The method according to claim 1, wherein the regional KPI associated with regional traffic comprises a mean travel time.

4. The method according to claim 1, wherein the regional KPI associated with regional traffic comprises a mean travel speed.

5. The method according to claim 1, wherein the regional KPI associated with regional traffic comprises a volume-to-capacity ratio.

6. The method according to claim 1, wherein the LTS model comprises a microscopic traffic simulation tool programmed for generating key performance indicator data for traffic flow, queue length, traffic delays, and traffic safety information.

7. The method according to claim 1, wherein determining the opportunity area for improving the regional KPI comprises:
collecting travel demand data;
collecting roadway network data;
collecting infrastructure change information having data associated with one or more anticipated regional traffic infrastructure changes; and
benchmarking a traffic condition based on one or more of the travel demand data, roadway network data, and the infrastructure change information.

8. A system, comprising:
a processor; and
a memory for storing executable instructions, the processor programmed to execute the instructions to:
determine, via a Regional Traffic Simulation (RTS) model, an opportunity area for connected and automated vehicle (CAV) integrated traffic flow;
generate a regional key performance indicator (KPI) associated with the opportunity area;
model a regional KPI associated with local traffic in the opportunity area using a Local Traffic Simulation (LTS) model,
determining a local KPI associated with the opportunity area;
generate, based on the regional KPI, a tentative traffic solution associated with the opportunity area;
connect, via the processor, the LTS model to the RTS model using an outer feedback loop and modeling the tentative traffic solution, and determining a ripple effect of the tentative traffic solution via the RTS model, wherein the ripple effect is associated with a change to the LTS model; and
generate an infrastructure management plan comprising the change to the LTS model responsive to confirming an improvement to the regional KPI and the local KPI.

9. The system according to claim 8, wherein, the RTS model comprises a macroscopic traffic simulation tool programmed for microscopic traffic simulation.

10. The system according to claim 8, wherein the regional KPI associated with regional traffic comprises a mean travel time.

11. The system according to claim 8, wherein the regional KPI associated with regional traffic comprises a mean travel speed.

12. The system according to claim 8, wherein the regional KPI associated with regional traffic comprises a volume-to-capacity ratio.

13. The system according to claim 8, wherein the LTS model comprises a microscopic traffic simulation tool programmed for generating key performance indicator data for traffic flow, queue length, traffic delays, and traffic safety information.

14. The system according to claim 8, wherein the processor is further programmed to improve the regional KPI by executing the instructions to:
collect travel demand data;
collect roadway network data;
collect infrastructure change information having data associated with one or more anticipated regional traffic infrastructure changes; and
benchmark a traffic condition based on one or more of the travel demand data, roadway network data, and the infrastructure change information.

15. A non-transitory computer-readable storage medium in a computer, the computer-readable storage medium having instructions stored thereupon which, when executed by a processor, cause the processor to:
determine, via a Regional Traffic Simulation (RTS) model, an opportunity area for connected and automated vehicle (CAV) integrated traffic flow;
generate a regional key performance indicator (KPI) associated with the opportunity area;
model a regional KPI associated with local traffic in the opportunity area using a Local Traffic Simulation (LTS) model,
determining a local KPI associated with the opportunity area;
generate, based on the regional KPI, a tentative traffic solution associated with the opportunity area;
connect, via the processor, the LTS model to the RTS model using an outer feedback loop and modeling the tentative traffic solution, and determining a ripple effect of the tentative traffic solution via the RTS model, wherein the ripple effect is associated with a change to the LTS model; and
generate an infrastructure management plan comprising the change to the LTS model responsive to confirming an improvement to the regional KPI and the local KPI.

16. The non-transitory computer-readable storage medium according to claim 15, wherein the RTS model comprises a macroscopic traffic simulation tool programmed for microscopic traffic simulation.

17. The non-transitory computer-readable storage medium according to claim 15, wherein the regional KPI associated with regional traffic comprises a mean travel time.

18. The non-transitory computer-readable storage medium according to claim 15, wherein the regional KPI associated with regional traffic comprises a mean travel speed.

19. The non-transitory computer-readable storage medium according to claim 15, wherein the regional KPI associated with regional traffic comprises a volume-to-capacity ratio.

20. The non-transitory computer-readable storage medium according to claim 15, wherein the LTS model comprises a microscopic traffic simulation tool programmed for generating key performance indicator data for traffic flow, queue length, traffic delays, and traffic safety information.
